(19) United States
(12) Patent Application Publication
(10) Pub. No.: US 2022/0382940 A1
(43) Pub. Date: Dec. 1, 2022

(54) Simulation of a performance of an energy storage

(71) Applicant: NOVUM engineerING GmbH, Dresden (DE)

(72) Inventors: Valentin Boss, Dresden (DE); Amin Saidani, Dresden (DE)

(21) Appl. No.: 17/826,835

(22) Filed: May 27, 2022

(30) Foreign Application Priority Data
May 31, 2021 (EP) 21176804.9

(51) Int. Cl. G06F 30/27

(52) U.S. Cl. CPC G06F 30/27

(57) ABSTRACT

A simulation system and a method for simulating a performance of at least one storage unit of an energy storage. The simulation system includes at least one respective model for a respective storage unit of the energy storage. The encoder-decoder model includes at least one recurrent neural network or at least one neural network having a transformer architecture. The encoder processes an encoder input sequence that describes a measured temporal course of current and voltage or of power and voltage of the storage unit assigned to the model. The encoder generates an initial state of the model. The decoder processes a decoder input sequence describing a temporal course to be simulated of the current or of the power of the storage unit. The decoder generates a decoder output sequence that describes a simulated temporal course of the voltage of the storage unit assigned to the model.

### CROSS-REFERENCE TO RELATED APPLICATION

This application claims priority to European Patent Application No. EP 21 176 804.9 filed on May 31, 2021, which is incorporated by reference herein in its entirety.

### BACKGROUND

### 1. Field of Disclosure

The invention relates to a simulation system for simulating a performance of an energy storage.

### 2. Description of the Related Arts

DE 102019121461 B3 and WO 2021/023346 A1 describe a technology for monitoring a state of a battery, for example of a lithium-ion-battery, using a thermal simulation model. DE 102019111979 A1 and WO 2020/224724 A1 describe a method for server-side characterization of a rechargeable battery, wherein a simulation of an electrical state of the battery and of a thermal state of the battery is performed.

### SUMMARY

It is an object of the invention to provide a novel simulation system for simulating an energy storage, the system allowing for simulating a future behavior of the energy storage based on measured data of a respective storage unit of the energy storage. It is desirable to be able to draw conclusions as to a state of the storage unit or of the energy storage.

According to the invention, the object is solved by a simulation system for simulating a performance (that is, performance behavior) of at least one storage unit of an energy storage, wherein the simulation system comprises: at least one respective model for a respective storage unit of the energy storage, the storage unit being assigned to the model, wherein the model includes an encoder-decoder model having an encoder and a decoder, wherein the encoder-decoder model includes at least one recurrent neural network or at least one neural network having a transformer architecture, wherein the encoder is configured for processing an encoder input sequence that describes a measured temporal course (that is, a time course, chronological course or temporal progression) of current and voltage, or of power and voltage of the storage unit that is assigned to the model, wherein the processing of the encoder input sequence includes generating an initial state of the model from the encoder input sequence, and wherein the decoder is configured for processing a decoder input sequence while starting from the initial state of the model (that is, beginning with the model being in the initial state), the decoder input sequence describing a temporal course that is to be simulated of the current or, respectively, of the power of the storage unit that is assigned to the model, wherein the processing of the decoder input sequence includes generating a decoder output sequence from the decoder input sequence while starting from the initial state of the model (that is, beginning with the model being in the initial state), the decoder output sequence describing a simulated temporal course of the voltage of the storage unit that is assigned to the model. The decoder output sequence and/or the temporal course of the voltage that is described by the decoder output sequence may be output by the system.

Thus, the decoder of the encoder-decoder model is configured to simulate, starting from the initial state, a subsequent performance, wherein a temporal course of the current or, respectively, of the power is specified, in order to obtain a simulated temporal course of the voltage. The processing of the encoder input sequence by the encoder of the encoder-decoder model is performed in order to generate a state of the model that represents in the model the state of the real storage unit after going through the measured temporal course of the current and the voltage, or of the power and the voltage. This initializing of the model brings the model into its initial state.

Thus, it is a basic idea of the invention to provide a simulation system for simulating a current-voltage behavior or a power-voltage behavior of an energy storage, wherein, by using a recurrent neural network, the system makes it possible that, based on measured data of a respective storage unit of the energy storage, for a subsequent hypothetical current course or power course, a voltage course of the storage unit may be simulated. For example, this may make it possible to estimate state properties of the storage unit or of the energy storage from a simulated voltage course. On the basis of recorded field data and machine learning methods, the model (or battery model) is built, or a plurality of models for respective storage units. The model allows for almost real time-capable simulations, on the basis of which the battery state may be determined. It is advantageous that on the basis of the model, the simulation allows for a precise prediction of the behavior of the storage unit and, therefore, of the energy storage, on the basis of which desired state variables may be derived such as SoH (State of Health), SoC (State of Charge) and SoF (State of Function). Thus, possible vulnerabilities may be found at an early stage, an operation of the energy storage may be optimized by an energy storage management system (reduction of the current, of the power, or of the load), and/or an outputting of maintenance information may be performed for the respective storage units or, respectively, cells or modules. Thereby, the self-reinforcing effect of battery aging is delayed, and a prolonged service life of the batteries is made possible.

It is particularly advantageous that a model is provided that, on the one hand, may be particularly well adapted to the performance of a real storage unit by machine learning and without requiring a physical modelling on the basis of internal characteristics of the storage unit, and that, on the other hand, may be used for simulating concrete profiles of requirements. For example, conventional models for battery state prediction often have the problem that an initial state with regard to the state of charge SoC (State of Charge) and the SoH (State of Health) of the battery must be determined. In contrast, the encoder-decoder model architecture learns to determine the initial state from the historic data of the cell and does not model the initial state through an assumption. The internal representation of the model is of a mathematical nature and only aims at approximating the battery behavior, not at physically interpreting the behavior. The model may be trained on the basis of historical measurement data. Furthermore, for example, it may be made possible to automatically reduce deviations of the model through online training and through an improvement of the model resulting therefrom. In practice, battery voltage and battery current frequently are the only measurable physical variables that allow for making a statement about the battery behavior. The simulation system may particularly well evaluate these variables. The model may be continuously adapted during operation of the energy storage.

For example, the performance (or performance behavior) may include a current-voltage behavior or a power-voltage behavior. A current-voltage behavior may describe the course of the voltage as a function of (depending on) the course of the current. A power-voltage behavior may describe the course of the voltage as a function of (depending on) the course of the power.

The encoder input sequence describes a measured temporal course of current and voltage or of power and voltage of the storage unit that is assigned to the model. This may be done by indicating values of current and voltage. Or, for example, this can be done by indicating values of power and voltage, because the current may be defined by indicating voltage and power, for example.

Recurrent neural networks are a class of artificial neuronal networks that comprise connections between neurons or nodes of a layer to neurons or nodes of a same or a preceding layer and thereby are specifically adapted for processing sequential input data. A neural network having a transformer architecture is also called a transformer and is a deep-learning architecture that is specifically adapted to processing sequential input data.

Preferably, the simulation system is a simulation system for simulating a performance of a plurality of storage units of an energy storage, wherein the simulation system comprises: at least one respective model for a respective storage unit of the energy storage, the storage unit being assigned to the model. Thus, in each of the models, there is processed a respective encoder input sequence and a respective decoder input sequence, and a respective decoder output sequence is generated. The described operations are performed for the respective individual models, which are assigned to the respective storage units of the energy storage, from which the respective measured data originate (stem from). Combining the models allows for predicting the behavior of (whole) energy storage. A combined evaluating of the decoder output sequences may performed. For example, based on the respective generated decoder output sequences, which respectively describe a simulated temporal course of the voltage of the storage unit that is assigned to the respective model, a simulated temporal course of a total voltage of the energy storage may be determined, or an estimated value of a state parameter may be determined that characterizes a state of the energy storage, or it may be predicted whether the energy storage can fulfill a load scenario (such as described in detail in the following for a respective unit). The system may output the decoder output sequence and/or the temporal course of the voltage described by the decoder output sequence and/or the result of the evaluating or the checking and/or information about the prediction.

The energy storage may be called a storage for electric energy. It may be a storage for electric energy on an electrical basis or an electro-chemical basis. The energy storage may be an electrical energy storage or an electro-chemical energy storage, for example a battery. In the following, the energy storage is also synonymously called a battery.

The performance of the energy storage is simulated (in particular) on the level of the storage unit(s). A simulation of each single (individual) cell or storage unit allows for predicting the behavior and the state of the entire storage.

Preferably, the energy storage is configured for enabling measurements of current and voltage or of power and voltage of the respective storage unit. In particular, the energy storage may be configured for enabling measurements of current and voltage or of power and voltage of the respective storage unit during operation of the energy storage. For example, the respective storage unit may be a storage unit of an energy storage that is composed of a plurality of storage units. For example, the respective storage unit may be a storage cell or battery cell, or may be a storage module or battery module comprising a plurality of storage cells. In practice, preferably, the smallest unit of the energy storage of which current data/power data and voltage data can be measured and provided to the simulation system is selected as a storage unit. For example, the storage unit may comprise a plurality of storage cells that may be arranged in series connection and/or parallel connection. Preferably, storage units that are modeled by the models are storage units for which respective measured values of a storage and of a current or, respectively, a power are available or can be measured.

The encoder input sequence describes a measured temporal course of current and voltage or of power and voltage of the storage unit that is assigned to the model. For example, the encoder input sequence may include values of the voltage and values of the current or of an electrical charge or of the power. Preferably, the encoder input sequence describes a current (present) and/or most recently measured temporal course of current and voltage or of power and voltage of the storage unit assigned to the model. The initial state of the model then represents a current (present) state of the corresponding storage unit.

The simulation system may be configured for providing an encoder input sequence, based on a series of measurements of data fed into the simulation system, which include a measured temporal course of current and voltage or of power of voltage of the storage unit assigned to the model, the encoder input sequence corresponding to the series of measurements, and for supplying the encoder input sequence to the respective model for processing.

In order to simplify the calculations, preferably, the encoder input sequence and the decoder input sequence (as well as the training sequence described in the following, where applicable) consistently include values of a current, values of an electrical charge, values of a power, and/or both values of a current and values of an electrical charge. An electrical charge corresponds to an integral of a current over time.

In practice, often the measured data are not available in constant temporal intervals. The simulation system may be configured for generating an encoder input sequence having elements in a fixed time grid from a measured temporal course of current and voltage or of power and voltage of the storage unit assigned to the model, for example by interpolating. Likewise, the simulation system may be configured for generating a decoder input sequence having elements in a fixed time grid from a measured temporal course of current or voltage of the storage unit assigned to the model. In practice, intervals in the range of 1s to 10s are sufficient for many applications.

For example, the state of the model may be represented by a state vector of the model that is generated by the encoder and processed by the decoder. The encoder-decoder model is particularly well suited for representing a state of the storage unit, initializing by the encoder input sequence, and simulating the subsequent behavior of the storage unit by processing the decoder input sequence.

For example, the encoder may be a recurrent neural network. For example, the decoder may be a recurrent neural network.

For example, the encoder-decoder model may include a neural network having a transformer architecture, and the transformer architecture may include the encoder and the decoder. In other words, the encoder-decoder model may be a transformer model that includes the encoder and the decoder.

Preferably, the respective encoder comprises a first encoder layer and at least one second encoder layer. One or the first decoder layer preferably is arranged downstream of the second encoder layer. Preferably, the first encoder layer is configured for processing the encoder input sequence as input. Preferably, the second (or a last second) encoder layer is configured for generating the initial state of the model.

Preferably, the respective decoder comprises a first decoder layer and at least one second decoder layer. Preferably, the second decoder layer is arranged downstream of the first decoder layer. The first decoder layer is arranged downstream of the encoder. Preferably, the first decoder layer is configured for processing the decoder input sequence, while starting from the initial state of the model. Preferably, the second (or a last second) decoder layer is configured for generating the decoder output sequence.

Here, the term “downstream” means arranged downstream with respect to the (main) processing direction.

The first encoder layer, the second encoder layer, the first decoder layer, and the second decoder layer may, for example, each comprise a respective neural network and/or partial layers of at least one neural network of the encoder or, respectively, the decoder. For example, the numbers of the encoder layers and decoder layers may be determined empirically and may be increased until a satisfying function is achieved.

Temperature, current or, respectively, power, and pressure on the battery are important influencing variables of the battery behavior. Simply put, the voltage results depending on these variables, on the state of charge and on the aging of the battery.

In embodiments, the encoder input sequence describes the measured temporal course of current and voltage or of power and voltage of the storage unit assigned to the model and a measured temporal course of a temperature.

In embodiments, the decoder input sequence describes the temporal course to be simulated of the current or of the power of the storage unit assigned to the model and a temporal course to be simulated of a temperature.

Thereby, it is possible to also take into account the temperature for the modelling of the state of the respective storage unit. The temperature is an important influencing variable for the battery behavior of a battery. For example, the temperature may be an ambient temperature of the storage unit or of the energy storage, or may be a temperature of the storage unit or of the energy storage.

In embodiments, the respective encoder and/or the respective decoder is a recurrent neuronal network having an LSTM architecture or a GRU architecture or is a Convolutional Neural Network, CNN.

LSTM (long short-term memory) denotes an architecture in which a cell of the neural network has an input gate, a forget gate, and an output gate. For example, a B-LSTM architecture may be provided (bidirectional long short-term memory). GRU (gated recurrent unit) denotes an architecture in which a cell of the neural network has an input gate and a forget gate.

Thereby, an improved adapting of the model to the data or to the encoder input sequence is made possible, in particular for multi-layered recurrent neural networks.

In embodiments, the simulation system is configured for predicting whether the respective storage unit of the energy storage can fulfill a load scenario, wherein the predicting comprises: processing a respective encoder input sequence by the encoder of the model to which the respective storage unit is assigned, wherein the encoder input sequence describes a last measured (that is, most recently measured) temporal course of current and voltage or of power and voltage of the storage unit assigned to the model, wherein the processing of the encoder input sequence comprises generating an initial state of the model from the encoder input sequence; and, starting from the initial state of the model (that is, beginning with the model being in the initial state), processing a respective decoder input sequence by the decoder of the model, to which the respective storage unit is assigned, wherein the decoder input sequence model in accordance with the load scenario describes a temporal course to be simulated of the current or of the power of the storage unit assigned to the model (that is, the temporal course to be simulated is described in accordance with the load scenario), wherein the processing of the decoder input sequence comprises, while starting from the initial state of the model (that is, beginning with the model being in the initial state), generating a decoder output sequence from the decoder input sequence, wherein the decoder output sequence describes a simulated temporal course of the voltage of the storage unit assigned to the model; and checking whether the generated decoder output sequence fulfills the load scenario, and if this is the case, predicting that the load scenario can be fulfilled, and otherwise predicting that the load scenario cannot be fulfilled.

Since the model is initialized based on the last measured temporal course of current and voltage or of power and voltage of the storage unit assigned to the model, the initial state of the model can represent the current (present) state of the storage unit. This makes it possible to make a prediction about whether the load scenario is fulfillable. In particular, it is possible to make a statement about the capability of the system to fulfill an individually defined load scenario. For example, when the simulated temporal course of the voltage decreases to a value that is inadmissibly low, it may be predicted that in the current (present) state of the storage unit, the load scenario cannot be fulfilled. Thus, it may be checked whether the simulated temporal course of the voltage together with the temporal course to be simulated of the current or of the power according to the load scenario fulfills the load scenario. For example, the load scenario may describe a minimum voltage that must be complied with during the described course of the current/the power. For example, the checking whether the generated decoder output sequence fulfills the load scenario may include checking whether the simulated temporal course of the voltage fulfills the load scenario. For example, the checking whether the generated decoder output sequence fulfills the load scenario may include checking whether the simulated temporal course of the voltage complies with the minimum voltage. Furthermore, a prediction about anomalies occurring during operation of the battery may be provided based on a load scenario: if a load scenario is not fulfilled, this may correspond to the occurring of an anomaly. The system may output the decoder output sequence and/or the temporal course of the voltage described by the decoder output sequence and/or the result of the evaluating or the checking and/or information about the prediction.

For example, a decoder input sequence may be used that describes a current drain profile to be simulated, wherein the current drain profile maintains a minimum current over a duration of time, and the generated decoder output sequence may be evaluated to determine a duration of time after which a minimum voltage of the load scenario is not complied with anymore (that is, the voltage falls below the minimum voltage) and/or whether a duration of time that is demanded according to the load scenario is achieved. For example, a decoder input sequence may be used that describes a power profile to be simulated, wherein the power profile maintains a minimum power over a duration of time, and the generated decoder output sequence may be evaluated to determine a duration of time after which a minimum voltage of the load scenario is not complied with anymore (that is, the voltage falls below the minimum voltage), and/or whether a duration of time that is demanded according to the load scenario is achieved.

In embodiments, the simulation system is configured for estimating a state parameter that indicates a state of the respective storage unit of the energy storage, wherein the estimating of the state parameter includes: processing a respective encoder input sequence by the encoder of the model to which the respective storage unit is assigned, wherein the encoder input sequence describes a last measured (that is, most recently measured) temporal course of current and voltage or of power and voltage of the storage unit assigned to the model, wherein the processing of the encoder input sequence includes generating an initial state of the model from the encoder input sequence; and, starting from the initial state of the model, processing a respective decoder input sequence by the decoder of the model to which the respective storage is assigned, wherein the decoder input sequence describes a temporal course to be simulated of the current or of the power of the storage unit that is assigned to the model, wherein the processing of the decoder input sequence includes, while starting from the initial state of the model, generating a decoder output sequence from the decoder input sequence, wherein the decoder output sequence describes a simulated temporal course of the voltage of the storage unit assigned to the model; and determining an estimated value of the state parameter on the basis of the temporal course to be simulated of the current or of the power and based on the associated (that is, the corresponding) simulated course of the voltage. The system may output the decoder output sequence and/or the temporal course of the voltage described by the decoder output sequence and/or the estimated value.

For example, by simulating a discharging of the storage unit up to an end-point voltage, the current (present) state of charge may be estimated as a state parameter. Thus, individual state variables and analysis functions may be provided that allow for statements about the battery behavior that are more precise than conventional state variables such as a charge-based estimation of the SoH or the SoC, for example. For example, the state parameter to be estimated may include state parameters that are dependent on the current profile and/or power profile, such as SoH, SoC and SoF.

In embodiments, the simulation system is configured for comparing the simulated temporal course of the voltage to a further measured temporal course of the voltage of the storage unit assigned to the model, and for determining an indicator of a rating of the model (that is, of the model accuracy) from the result of the comparison. The system may output the decoder output sequence and/or the temporal course of the voltage described by the decoder output sequence and/or the result of the comparison and/or the indicator.

Preferably, the decoder input sequence describes a further measured temporal course of the current or of the power of the storage unit that is assigned to the model. Here, the initial state represents the current (present) state of the storage unit, corresponding to the last measured temporal course of current and voltage or of power and voltage. Thereby, it is made possible to check how well the corresponding simulated temporal course of the voltage matches the corresponding measured temporal course of the voltage. Here, the simulated voltage is a measure of the accuracy of the model. And the simulated voltage in conjunction with the actually measured voltage is an indicator of the rating of the model (that is, model accuracy). In the operation of the energy storage, conclusions about the rating of the model may be drawn based on deviations of the simulated voltage from the actually measured voltage. The achieved model accuracy may be evaluated using historical data that are stored in a data base. This makes it possible to make a good statement and often the only statement about the behavior of the battery or about the state variables output by a system, because the battery voltage is one of the few measurable state variables in most systems. Deviations from the simulated behavior may be used for detecting anomalies and for acute improvements of the model, in order to optimize future predictions. For example, the comparing may include a determining of a correlation, a coefficient of determination, for example the coefficient of determination R2, or a mean deviation.

The respective model may be trained on the basis of training data. The simulation system may be configured for training the respective model on the basis of training data. The training data for the respective model include a plurality of training sequences, wherein a respective training sequence describes a measured temporal course of current and voltage or of power and voltage of the storage unit assigned to the model. When the model is trained on the basis of a respective training sequence, the encoder processes an encoder input sequence that corresponds to a first section of the training sequence and that describes a measured temporal course of current and voltage or of power and voltage of the storage unit assigned to the model. The decoder processes a decoder input sequence that corresponds to a second section of the training sequence and that describes a measured temporal course of the current or of the power of the storage unit assigned to the model. The generated decoder output sequence describes a simulated temporal course of the voltage of the storage unit assigned to the model. The model is then adapted on the basis of deviations of the generated decoder output sequence from a temporal course of the voltage according to the second section of the training sequence. In this manner, the simulation system may be trained on the basis of measured data of the storage unit(s). An evaluating of the deviations may include an evaluating of a model accuracy (or rating) of the model, for example.

In case of a simulation system for a plurality of storage units that is to be newly trained, a general model for all of the storage units may be trained first, for example, and then, starting from the trained general model, individual models for the respective storage units may be trained on the basis of measured data of the respective storage units. For example, the individual models may even be trained further during operation of the simulating method. After a training, there exists an individual model for each battery or each cell in the system.

In embodiments, the simulation system is configured for training the respective model on the basis of training data, wherein training data for the respective model include a plurality of training sequences, wherein a respective training sequence describes a measured temporal course of current and voltage or of power and voltage of the storage unit assigned to the model, wherein the training of the respective model comprises, for a respective training sequence: processing an encoder input sequence by the encoder, wherein the encoder input sequence corresponds to a first section of the training sequence and describes a measured temporal course of current and voltage or of power and voltage of the storage unit assigned to the model, wherein the processing of the encoder input sequence includes generating an initial state of the model from the encoder input sequence; starting from the initial state of the model, processing a decoder input sequence by the decoder, wherein the decoder input sequence corresponds to a second section of the training sequence and describes a measured temporal course of the current or of the power of the storage unit assigned to the model, wherein the processing of the decoder input sequence includes, while starting from the initial state of the model, generating a decoder output sequence from the decoder input sequence, wherein the decoder output sequence describes a simulated temporal course of the voltage of the storage unit assigned to the model; and adapting the model based on deviations of the generated decoder output sequence from a temporal course of the voltage according to the second section of the training sequence.

This allows for adapting the simulation system to a changing state of the respective storage unit of the energy storage. In particular, the training data may include new training sequences, wherein a respective new training sequence describes a newly measured temporal course of current and voltage or of power and voltage of the storage unit assigned to the model. This allows for adapting the simulation system in a case of a degradation of the energy storage. This enables the system to smartly adapt itself with respect to its analysis functions to the tasks that are set for the analyzing system during the lifetime of the system. An adaptive simulation system is made possible: errors in the prediction may lead to more precise models and to an improved prediction of the voltage and an improved prediction of the state variables of the battery by further learning (training) of the model.

The simulation system may be used for simply upgrading existing energy storage management systems, because only historical data are needed.

According to a further development of the invention, the problem is solved by an energy storage management system for an energy storage having at least one storage unit, the system comprising a data storage (that is, a memory) for storing a respective measured temporal course of current and voltage or of power and voltage of the respective storage unit, wherein the energy storage management system further comprises a simulation system as described above.

For example, the energy storage management system may include a measuring apparatus for measuring current and voltage or power and voltage of the respective storage unit of the energy storage, wherein the energy storage management system is configured for storing respective measured temporal courses of current and voltage or of power and voltage of the respective storage unit in the data storage. For example, the data storage may be or may include a data base in which the respective measured temporal course of current and voltage or of power and voltage of the respective storage unit is stored.

The object is further solved by a method for simulating a performance of at least one storage unit of an energy storage by a simulation system that includes at least one respective model for a respective storage unit of the energy storage, the storage unit being assigned to the model, wherein the model includes an encoder-decoder model having an encoder and a decoder, wherein the encoder-decoder model includes at least one recurrent neural network or at least one neural network having a transformer architecture, wherein the method includes the steps of: processing an encoder input sequence by the encoder and generating an initial state of the model, wherein the encoder input sequence describes a measured temporal course of current and voltage or of power and voltage of the storage unit assigned to the model; and processing a decoder input sequence by the decoder and generating a decoder output sequence, wherein the decoder input sequence describes a temporal course to be simulated of the current or of the power of the storage unit assigned to the model, and wherein the decoder output sequence describes a simulated temporal course of the voltage of the storage unit assigned to the model.

The method may include the operations of the simulation system described above as steps of the method, in particular operations by the encoder, by the decoder, and by the simulation system, such as the predicting whether the respective storage unit of the energy storage can fulfil a load scenario, including the mentioned steps of processing and checking; the estimating of a state parameter indicating a state of the respective storage unit of the energy storage, including the mentioned steps of processing and of determining an estimated value; the comparing of a simulated temporal course of the voltage to a further measured temporal course of the voltage, and the determining of an indicator of a rating of the model (model accuracy); the outputting of the mentioned decoder output sequences and/or of the temporal course of the voltage that is described by the decoder output sequences and/or of the further mentioned results, predictions, estimated values, indicators; the training of the respective model on the basis of training data including the mentioned steps of processing and of adapting the model. The simulation system may correspond to the above-described simulation system.

### BRIEF DESCRIPTION OF THE DRAWINGS

In the following, preferred embodiment examples will be further explained on the basis of the Figures.

FIG. 1 shows a schematical representation of an energy storage management system having a simulation system according to an embodiment.

FIG. 2 shows a schematic representation of the using of training sequences for training the simulation system.

FIG. 3 shows a schematic representation of current-voltage courses.

FIG. 4 shows a schematic representation of current-voltage courses and of a simulation accuracy (rating of the simulation).

### DETAILED DESCRIPTION

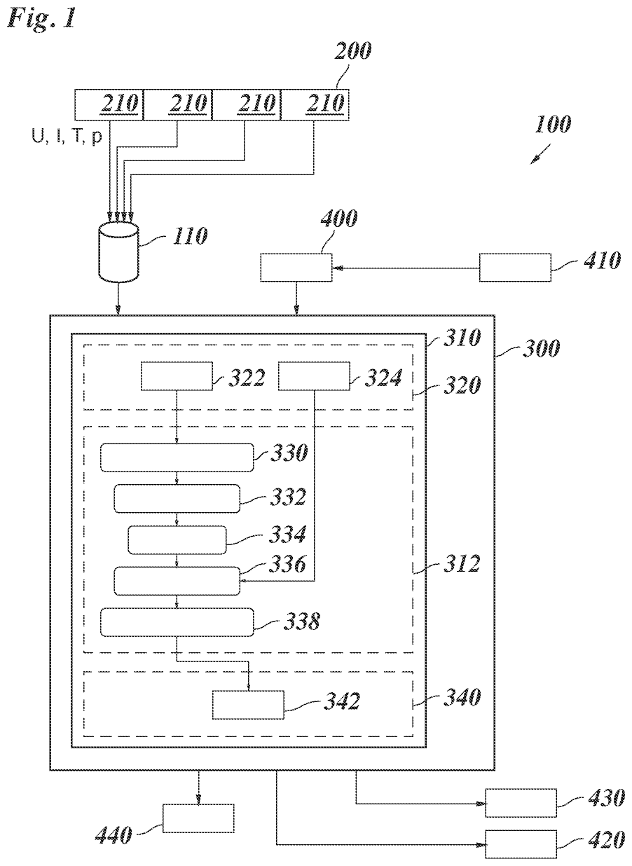

FIG. 1 schematically shows an energy storage management system 100 and an electrochemical energy storage 200 having a plurality of storage units 210. For example, the storage units 210 may be storage cells or storage modules. The energy storage management system 100 includes a memory (data storage) 110 for storing measured values of a voltage U, a current I, a temperature T and, if applicable, a pressure p of the respective storage units 210. In the following, the usage of values of the current I is described, for example, for input sequences and for courses to be simulated. However, the invention is not limited to this. For example, instead of the current I, the power P may be used.

The energy storage management system 100 includes a simulation system 300, which includes for each storage unit 210 a respective assigned model 310. For reasons of clarity, one model 310 is exemplarily shown in FIG. 1.

The model 310 includes an encoder-decoder model 312 for processing input sequences 320 or input vectors, which are also called an input or input features. The encoder-decoder model 312 generates output sequences 340 or output vectors, which are also called an output or output features. The encoder-decoder model 312 includes a first encoder layer 330 and a second encoder layer 332, which generate a model state 334 by processing an encoder input sequence 322. The model 310 further comprises a first decoder layer 336 and a second decoder layer 338. The first decoder layer 336 processes a decoder input sequence 324. The second decoder layer 338 generates a decoder output sequence 342. For example, the layers 330, 332, 336, 338 may be recurrent neural networks.

Each of the encoder input sequences 322 respectively describes a measured temporal course of current I and voltage U of the storage unit 210 assigned to the model 310. The input sequences 322 may be selected from the measured values stored in the memory 110 and/or may be interpolated from the stored measured values. An initial model state 334 is generated by processing the encoder input sequence 322. While stepwise processing the encoder input sequence 322, the encoder-decoder model 312 stepwise updates its state. The model 310 is brought into the initial state 334, which corresponds to a state of the storage unit 210, which storage unit is to be simulated.

Depending on the application, the decoder input sequences 324 describe a measured temporal course of the current I of the storage unit 210 assigned to the model 310, or a course 400 to be simulated of the current I of the storage unit 210 assigned to the model 310. For example, the course 400 of the current Ito be simulated may be defined by a load scenario 410 which is input into the energy storage management system 100 as an input.

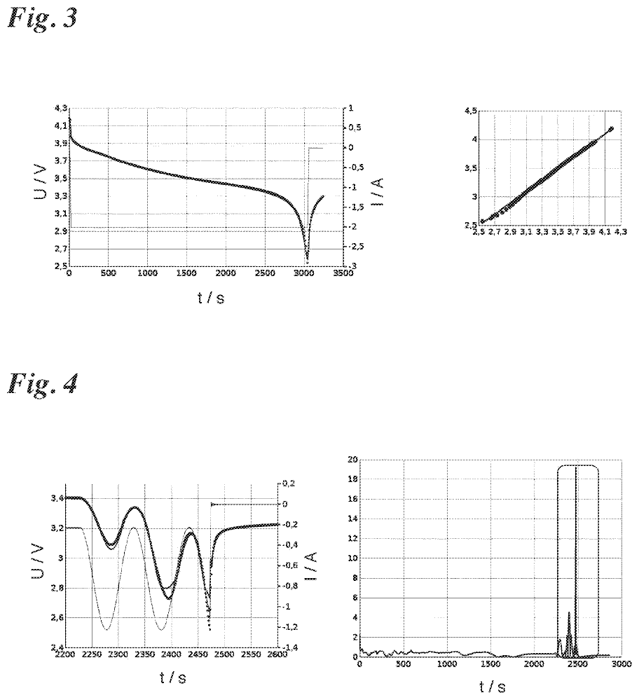

In a simulation run, the model 310 processes the decoder input sequence 324 and generates a decoder output sequence 342, wherein, initially, the model 310 has the initial state 334. While stepwise processing the decoder input sequence 324, the decoder output sequence 342 is stepwise generated, wherein the encoder-decoder model 312 stepwise updates its state, wherein in a respective step, the encoder-decoder model 312 processes a current (electrical current) value, the encoder-decoder model 312 updates its state, and the encoder-decoder model 312 generates a voltage value of the decoder output sequence 342. For example, this makes it possible to perform a simulation of a discharging by a defined current and to output a value for this discharging process for this discharging process (SoHic). An example thereof is shown in FIG. 3.

Depending on the application, for example, an output 340 of the model 310 may include an estimated value 420 of a state parameter of a respective storage unit 210 of the energy storage 200, or a prediction 430 about whether the load scenario 410 is fulfillable by the respective storage unit 210 or, respectively, by the energy storage 200 in its present condition. Voltage values of the output 340 that are output may also include mean values and standard deviation of the voltage. Furthermore, an output 340 may include an indicator 440 of a rating of the respective model 310 (model accuracy). It is possible to evaluate the model accuracy through correlating the simulated values and the subsequently actually measured values. For example, this may be done through a correlation, the coefficient of determination R², or the mean deviation. By examining the error, it is furthermore possible to evaluate weaknesses of the model 310 and to indicate estimated uncertainties for the simulated values. This is exemplarily shown in the diagrams of FIG. 4. Apart from the values of the current I or the current I and voltage U, the respective input sequences 320 may additionally also describe a course of the temperature T and, if applicable, a course of the mechanical pressure p for the respective storage unit 210. Accordingly, a respective simulated course 400 or a load scenario 410 may also include values for the temperature T and/or the pressure p.

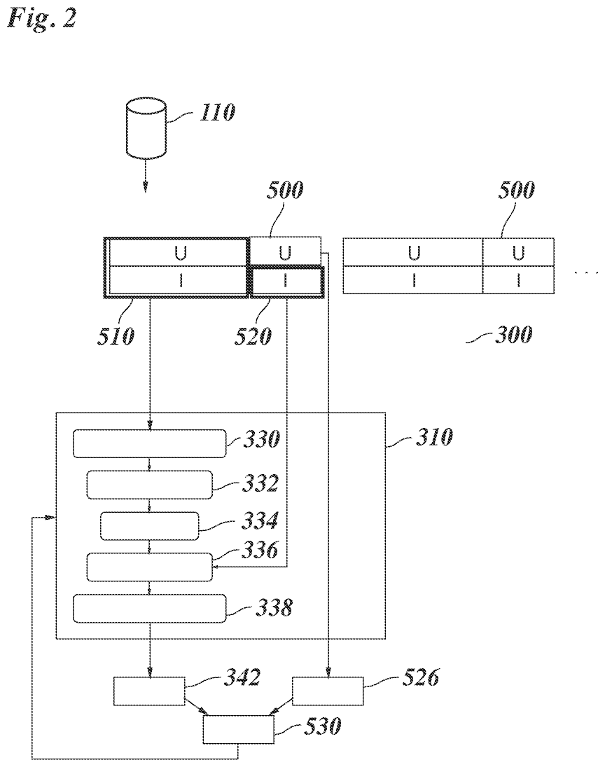

In a first step, the respective model 310 is trained for the corresponding storage unit 210 or storage cell. For this, historical data of voltage U, temperature T, current I and pressure p are used. FIG. 2 schematically shows the usage of training sequences 500, based on the stored measured data of the memory 110. Here, only voltage U and current I are exemplarily shown; however, temperature T and/or pressure p may be handled in the same manner as the current I. The respective training sequence 500 is divided into a first section 510 and a second section 520. An encoder input sequence 322 corresponds to the first section 510 and describes, in particular, the measured temporal course of current I and voltage U of the first section 510. The encoder/decoder ansatz (that is, approach) determines the initial state 334 (battery state) of the battery from, for example, the data (voltage U, current I and temperature T, and pressure p, where applicable) of the past 60 minutes, for example, corresponding to the first section 510. The initial state 434 is represented by a mathematical representation (corresponding to a matrix or a vector having a plurality of values), which cannot necessarily be physically interpreted. For example, this state 344 may be found or optimized through recursive neural networks (RNN) such as LSTM, GRU and others of the layers 330, 332.

Subsequently, this initial state 334 is used as an input value for the decoder 336, 338 (also in the form of RNN). The decoder 336 simulates the resulting voltage profile on the basis of the internal state and the expected current profile or temperature profile in accordance with an encoder input sequence 324. The decoder input sequence 324 is obtained from the second section 520 of the training sequence 500 and describes the measured temporal course of the current I in the second section 520 (as well as temperature T and pressure p, where applicable). A comparative sequence 526 is obtained from the second section 520 and describes the measured temporal course of the voltage U in the second section 520. A feedback unit 530 compares the comparative sequence to the output sequence 342 generated by the model 310, and the model 310 is adapted in accordance with the determined deviation.

For example, the trained simulation system 300 may be used for estimating a state variable of the storage unit 210. The left part of FIG. 3 exemplarily and schematically shows a temporal course of a current I (as a thin line), a measured voltage U (as dots) and a simulated voltage U (as a thick line) for a storage unit 210. In the example of FIG. 3, a discharging by a defined current of 2 A is simulated. Both the measured voltage and the simulated voltage decrease over time and finally fall below the end-point voltage. Based on this, for example, the simulation system 300 may determine a state parameter SoH_{1C}.

It is furthermore possible to continuously (or successively) train each model 310 using the (newly) measured data of its corresponding cell or storage unit 210. Thus, a precise digital representation of this cell or storage unit 210 is obtained, and precise model predictions and a statement about the individual desired battery state may be made on the basis thereof. By the gained knowledge, a user is enabled to adapt operation strategies and maintenance intervals to the battery state and the system state, and to actively react to deviations from the expected behavior. The right part of FIG. 3 schematically shows both the measured voltage (as a continuous line) in volts and the simulated voltage (as dots) in volts over the measured voltage in volts. It is found that there is a good correspondence.

The left part of FIG. 4 schematically shows a diagram of current and voltage courses, corresponding to the diagram of FIG. 3, for an example of a load scenario having a varying current I. The right part of FIG. 4 shows in mV a temporal course of the relative error of the simulated voltage as opposed to the measured voltage. The result of the comparison allows to draw conclusions about the accuracy of the model 310 and to selectively train the model 310 in determined regions of a larger deviation. By a specific training in these regions of larger deviation, an error that is obtained in these regions can be minimized.

What is claimed is:

1. A simulation system for simulating a performance of at least one storage unit of an energy storage, wherein the simulation system comprises:
at least one respective model for a respective storage unit of the energy storage, the storage unit being assigned to the model, wherein the model includes an encoder-decoder model having an encoder and a decoder, wherein the encoder-decoder model includes at least one recurrent neural network or at least one neural network having a transformer architecture,
wherein the encoder is configured for processing an encoder input sequence that describes a measured temporal course of current and voltage, or of power and voltage of the storage unit that is assigned to the model, wherein the processing of the encoder input sequence includes generating an initial state of the model from the encoder input sequence, and
wherein the decoder is configured for processing a decoder input sequence while starting from the initial state of the model, the decoder input sequence describing a temporal course that is to be simulated of the current or of the power of the storage unit that is assigned to the model, wherein the processing of the decoder input sequence includes generating a decoder output sequence from the decoder input sequence while starting from the initial state of the model, the decoder output sequence describing a simulated temporal course of the voltage of the storage unit that is assigned to the model.

2. The simulation system of claim 1, wherein the encoder input sequence describes the measured temporal course of current and voltage or of power and voltage of the storage unit assigned to the model and a measured temporal course of a temperature, and wherein the decoder input sequence describes the temporal course to be simulated of the current or of the power of the storage unit assigned to the model and a temporal course to be simulated of a temperature.

3. The simulation system of claim 1, wherein at least one of the respective encoder or the respective decoder is a recurrent neural network having an Long Short-Term Memory Network (LSTM) architecture or a Gated Recurrent Unit (GRU) architecture, or is a Convolutional Neural Network (CNN).

4. The simulation system of claim 1, wherein the simulation system is configured for predicting whether the respective storage unit of the energy storage fulfills a load scenario, wherein the predicting comprises:
processing a respective encoder input sequence by the encoder of the model to which the respective storage unit is assigned, wherein the encoder input sequence describes a last measured temporal course of current and voltage or of power and voltage of the storage unit assigned to the model, wherein the processing of the encoder input sequence comprises generating an initial state of the model from the encoder input sequence; and,
starting from the initial state of the model, processing a respective decoder input sequence by the decoder of the model, to which the respective storage unit is assigned, wherein the decoder input sequence in accordance with the load scenario describes a temporal course to be simulated of the current or of the power of the storage unit assigned to the model, wherein the processing of the decoder input sequence comprises, while starting from the initial state of the model, generating a decoder output sequence from the decoder input sequence, wherein the decoder output sequence describes a simulated temporal course of the voltage of the storage unit assigned to the model; and
checking whether the generated decoder output sequence fulfills the load scenario, and if the decoder output sequence fulfills the load scenario, predicting that the load scenario can be fulfilled, and if the decoder output sequence does not fulfill the load scenario, predicting that the load scenario cannot be fulfilled.

5. The simulation system of claim 1, wherein the simulation system is configured for estimating a state parameter that indicates a state of the respective storage unit of the energy storage, wherein the estimating of the state parameter includes:
processing a respective encoder input sequence by the encoder of the model to which the respective storage unit is assigned, wherein the encoder input sequence describes a last measured temporal course of current and voltage or of power and voltage of the storage unit assigned to the model, wherein the processing of the encoder input sequence includes generating an initial state of the model from the encoder input sequence; and,
starting from the initial state of the model, processing a respective decoder input sequence by the decoder of the model to which the respective storage is assigned, wherein the decoder input sequence describes a temporal course to be simulated of the current or of the power of the storage unit assigned to the model, wherein the processing of the decoder input sequence includes, while starting from the initial state of the model, generating a decoder output sequence from the decoder input sequence, wherein the decoder output sequence describes a simulated temporal course of the voltage of the storage unit assigned to the model; and
determining an estimated value of the state parameter based on the temporal course to be simulated of the current or of the power and based on the associated simulated course of the voltage.

6. The simulation system of claim 1, wherein the simulation system is configured for comparing the simulated temporal course of the voltage to a further measured temporal course of the voltage of the storage unit assigned to the model, and for determining an indicator of a rating of the model from the result of the comparison.

7. The simulation system of claim 1, wherein the simulation system is configured for training the respective model based on training data, wherein training data for the respective model include a plurality of training sequences, wherein a respective training sequence describes a measured temporal course of current and voltage or of power and voltage of the storage unit assigned to the model, wherein the training of the respective model comprises, for a respective training sequence:
processing an encoder input sequence by the encoder, wherein the encoder input sequence corresponds to a first section of the training sequence and describes a measured temporal course of current and voltage or of power and voltage of the storage unit assigned to the model, wherein the processing of the encoder input sequence includes generating an initial state of the model from the encoder input sequence;
starting from the initial state of the model, processing a decoder input sequence by the decoder, wherein the decoder input sequence corresponds to a second section of the training sequence and describes a measured temporal course of the current or of the power of the storage unit assigned to the model, wherein the processing of the decoder input sequence includes, while starting from the initial state of the model, generating a decoder output sequence from the decoder input sequence, wherein the decoder output sequence describes a simulated temporal course of the voltage of the storage unit assigned to the model; and
adapting the model based on deviations of the generated decoder output sequence from a temporal course of the voltage according to the second section of the training sequence.

8. An energy storage management system for an energy storage having at least one storage unit, the system comprising a data storage for storing a respective measured temporal course of current and voltage or of power and voltage of the respective storage unit,
characterized in that the energy storage management system further comprises a simulation system according to claim 1 for simulating a performance of the respective storage unit of the energy storage.

9. A method for simulating a performance of at least one storage unit of an energy storage by a simulation system that includes at least one respective model for a respective storage unit of the energy storage, the storage unit being assigned to the model, wherein the model includes an encoder-decoder model having an encoder and a decoder, wherein the encoder-decoder model includes at least one recurrent neural network or at least one neural network having a transformer architecture, wherein the method includes the steps of:
processing an encoder input sequence by the encoder and generating an initial state of the model, wherein the encoder input sequence describes a measured temporal course of current and voltage or of power and voltage of the storage unit assigned to the model; and
processing a decoder input sequence by the decoder and generating a decoder output sequence, wherein the decoder input sequence describes a temporal course to be simulated of the current or of the power of the storage unit assigned to the model, and wherein the decoder output sequence describes a simulated temporal course of the voltage of the storage unit assigned to the model.
